(19) United States
(12) Patent Application Publication
(10) Pub. No.: US 2025/0198004 A1
(43) Pub. Date: Jun. 19, 2025

(54) METHOD, INSERT AND APPARATUS FOR PROCESS CONTROL AND MONITORING OF THIN FILM DEPOSITION

(71) Applicant: PICOSUN OY, Espoo (FI)

(72) Inventors: Jesse KALLIOMÄKI, Masala (FI); Ilkka MANNINEN, Masala (FI)

(21) Appl. No.: 18/848,322

(22) PCT Filed: Mar. 13, 2023
(86) PCT No.: PCT/FI2023/050136

§ 371 Date: Sep. 18, 2024

(30) Foreign Application Priority Data
Mar. 21, 2022 (FI) 20225248

(51) Int. Cl. C23C 16/52; C23C 16/455

(52) U.S. Cl. CPC C23C 16/52; C23C 16/45544

(57) ABSTRACT

A method for determining penetration depth of a thin film process precursor, comprising providing an insert (100), arranging the insert (100) to contact a substrate (200) to form a plurality of spaces (101) in between the insert (100) and the substrate (200), and feeding the precursor(s) into the formed spaces (101) to determine the penetration depth of the precursor.

### TECHNICAL FIELD

The present disclosure generally relates to the field of semiconductors and substrate processing. The disclosure relates particularly, though not exclusively, to process control and monitoring of a thin film deposition process, such as atomic layer deposition (ALD).

### BACKGROUND

This section illustrates useful background information without admission of any technique described herein representative of the state of the art.

In the field of semiconductors and substrate processing, thin film deposition is used in almost every device. The atomic layer deposition (ALD) is vastly utilized as a thin film deposition method due to its conformal coating of various 3D shapes. Especially, ALD is advantageous as a deposition method for high aspect ratio (HAR) structures.

However, testing and quantifying the conformality as part of process control may be time consuming and expensive. The conventional testing procedure may comprise for instance fabricating a suitable test sample, depositing a thin film on the test sample, cutting, and preparing an appropriate sample for scanning electron microscopy (SEM) or transmission electron microscopy (TEM) imaging and analyzing the results from SEM and TEM imaging. The duration of the conventional procedure described above may be weeks and the estimated costs of such basic process control procedure thousands of euros.

### SUMMARY

The appended claims define the scope of protection. Any examples and technical descriptions of apparatuses, products and/or methods in the description and/or drawings not covered by the claims are presented not as embodiments of the invention but as background art or examples useful for understanding the invention.

It is an object of certain embodiments of the invention to provide an improved process control and/or monitoring method for thin film deposition or at least to provide an alternative solution to existing technology.

Accordingly, certain disclosed embodiments provide for an ingenious method for determining penetration depth of thin film process precursor(s).

According to a first example aspect of the invention there is provided a method for determining penetration depth of thin film process precursor(s), comprising:
providing an insert;
arranging the insert to contact a substrate to form a plurality of spaces in between the insert and the substrate; and
feeding the precursor(s) into the formed spaces to determine the penetration depth of the precursor(s).

In certain embodiments, the method comprises:
feeding the precursor(s) into the formed spaces in a reaction chamber housing the insert and the substrate.

In certain embodiments, the method comprises:
feeding the precursor(s) into the formed spaces by using an atomic layer deposition (ALD) sequence.

In certain embodiments, the formed spaces are elongated, confined, and/or closed at their one end. In certain embodiments, the formed spaces are in the form of a tunnel (or cavity).

In certain embodiment, the spaces have a curved shape. In certain embodiment, the spaces have a bendy shape. In certain embodiment, the spaces have a meandering shape. Accordingly, instead of being for example straight, the spaces may be curvy, and/or bendy, and/or meandering.

In certain embodiments, the spaces are closed at their one end, which one end is located opposite to the mouth of the space, which mouth is connected to an aperture in the middle of the insert.

In certain embodiments, the formed spaces are elongated spaces open at their one end, closed at their other end, and confined by the substrate and/or the insert along their width, the spaces preferably forming high aspect ratio structures.

In certain embodiments, the formed spaces are co-centric elongated cavities.

In certain embodiments, the insert comprises grooves, which grooves are configured to form said spaces in between the insert and the substrate when the insert and the substrate are in contact with each other.

In certain embodiments, the spaces have varying widths or varying heights.

In certain embodiments, the spaces have same lengths (depths). In certain embodiments, the flow area of the spaces is rectangular. In certain embodiments, the width of each of the spaces is equal but the height of the spaces varies. In certain embodiments, the height of each individual space is constant, but the width of the spaces varies.

In certain embodiments, the spaces are separate from each other, preventing the precursor(s) from flowing from one space directly into an adjacent space.

In certain embodiments, the insert is disk shaped and/or the shape of the insert is symmetrical around its centre.

In certain embodiments, the insert comprises an aperture in the centre of the insert, and the aperture is connected to the spaces to allow precursor feed into the spaces through the aperture of the insert. In certain embodiments, the aperture is symmetrically positioned in the centre of the insert. In certain embodiments, this enables each entry hole of the formed spaces to see similar flow geometry or similar flow conditions of the precursor(s). In certain embodiments, the precursor flow into the aperture is from the top.

In certain embodiments, the precursor(s) enter the spaces via diffusion. In certain embodiments, the precursor(s) flow within the spaces via diffusion.

In certain embodiments, the insert and the substrate are horizontally oriented, the insert resting on top of the substrate.

In certain embodiments, the method comprises:
determining the penetration depth by measuring a thin film coating formed on the substrate.

In certain embodiments, the method comprises:
obtaining results from the measurement of the thin film formed on the substrate and adjusting the thin film process according to the obtained results.

In certain embodiments, the measuring comprises analysis of precursor penetration depth via ellipsometry characterization or quantitative visual inspection.

In certain embodiments, results from the measurement of the thin film formed on the substrate are provided to an operator. In certain embodiments, an associated apparatus comprises at least one processor, and at least one memory including a computer program (or computer program code), wherein the at least one memory and the computer program (code) are configured, with the at least one processor, to provide the operator with results from the measurement of the thin film formed on the substrate. The associated apparatus may be a data processing device, or a computer. Said data processing device or computer may be implemented as a part of a deposition reactor process control system, or separately. Herein, the deposition reactor is considered as a deposition reactor, for example an ALD reactor, comprising the reaction chamber.

In certain embodiments, data visualization is provided to the operator. In certain embodiments, appropriate process descriptive parameter(s) and data visualization are provided to the operator. In certain embodiments, input data for the computer program and/or a related data analysis is obtained by the aforementioned method(s).

In certain embodiments, the measuring of the precursor penetration depth is performed from the aperture towards the ends of the spaces.

In certain embodiments, the substrate is a planar substrate, for example a wafer, such as a semiconductor wafer, for example a silicon wafer.

In certain embodiments, said determining the penetration depth by measuring a thin film coating formed on the substrate comprises analyzing obtained measurement data (which may be received from a measurement device) by at least one processor; and providing an operator with measurement results based on the analysis.

According to a second example aspect of the invention there is provided an insert configured to contact a substrate to form a plurality of spaces in between the insert and the substrate for determining penetration depths of thin film process precursor(s) with the method of the first example aspect or any of its embodiments.

Accordingly, in the second example aspect there is provided an insert configured to de used in the method of the first example aspect or any of its embodiments.

In certain embodiments, the insert comprises grooves configured to form said spaces when the insert and the substrate contact each other.

In certain embodiments, the insert is a separate part. In certain embodiments, the insert does not form part of the substrate. In certain embodiments, the insert is a part that is placeable to contact the substrate. In certain embodiments, the insert is a part placeable on top of the substrate. In certain embodiments, the insert is removable. In certain embodiments, the insert is removably contactable with the substrate.

In certain embodiments, the insert is re-usable (i.e. repeatedly usable). This means that the same insert is usable multiple times. In certain embodiments, the insert is removably contactable with the substrate and re-usable. In certain embodiments, the insert is usable in process control and/or monitoring of multiple thin film processes. In certain embodiments, the insert is usable in process control and/or monitoring of all thin film processes of certain facility.

According to a third example aspect of the invention there is provided an apparatus comprising at least one processor, and at least one memory including computer program code (or a computer program), wherein the at least one memory and the computer program code (or computer program) are configured, with the at least one processor, to cause the apparatus to perform:
feeding of precursor(s) into a plurality of spaces formed in between an insert and a substrate by arranging the insert to contact the substrate; and
determining the penetration depth of the precursor(s) in the formed spaces.

According to a fourth example aspect of the invention there is provided a computer program comprising computer executable program code which when executed by a processor causes an apparatus to perform:
feeding of precursor(s) into a plurality of spaces formed in between an insert and a substrate by arranging the insert to contact the substrate; and
determining the penetration depth of the precursor(s) in the formed spaces.

According to a fifth example aspect of the invention there is provided an apparatus configured to perform a thin film deposition process and comprising the insert of the second example aspect or any of its embodiments.

In certain embodiments, the insert is formed from a polymer and a rigid material. In certain embodiments, the rigid material comprises metal or ceramic material.

Different non-binding example aspects and embodiments have been illustrated in the foregoing. The embodiments in the foregoing are used merely to explain selected aspects or steps that may be utilized in different implementations. Some embodiments may be presented only with reference to certain example aspects. It should be appreciated that corresponding embodiments may apply to other example aspects as well.

### BRIEF DESCRIPTION OF THE FIGURES

Some example embodiments will be described with reference to the accompanying figures, in which:

FIG. 1 shows a flow chart of a method according to an example embodiment;

FIG. 2a schematically shows an insert according to an example embodiment;

FIG. 2b schematically shows an insert according to another example embodiment;

FIG. 3a schematically shows an insert according to yet another example embodiment;

FIG. 3b schematically shows an insert according to yet another example embodiment;

FIG. 3c schematically shows an insert according to yet another example embodiment;

FIG. 4a schematically shows a location of a cross-section of the insert;

FIG. 4b schematically shows the cross-section taken at the location shown in FIG. 4a; schematically shows a further location of another cross-section of the insert; FIG. 5a

FIG. 5b schematically shows the cross-section taken at the location shown in FIG. 5a; schematically shows a magnified view of an edge of the insert according to an FIG. 5c example embodiment;

FIG. 6a schematically shows a side view of a substrate holder according to an example embodiment;

FIG. 6b schematically shows a magnified view of an edge of the substrate holder according to an example embodiment;

FIG. 6c schematically shows a substrate holder from above according to an example embodiment;

FIG. 7a schematically shows the insert, the substrate and the substrate holder according to an example embodiment;

FIG. 7b schematically shows the insert, the substrate and the substrate holder including the feed of the precursor according to an example embodiment;

FIG. 7c schematically shows a flow path of the precursor according to an example embodiment;

FIG. 8 schematically shows a magnified view of the insert, the substrate and the substrate holder edges;

FIG. 9a schematically shows the substrate after the precursor deposition according to an example embodiment;

FIG. 9b shows a visualization of penetration depth analysis results in certain embodiments;

FIG. 10 shows a process control system in accordance with certain embodiments; and

FIG. 11 schematically shows an apparatus according to an example embodiment.

### DETAILED DESCRIPTION

In the following description, Atomic Layer Deposition (ALD) technology are used as an example.

The basics of an ALD growth mechanism are known to a skilled person. ALD is a special chemical deposition method based on sequential introduction of at least two reactive precursor species to at least one substrate. A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness. Deposition cycles can also be either simpler or more complex. For example, the cycles can include three or more reactant vapor pulses separated by purging steps, or certain purge steps can be omitted. Or, as for plasma-assisted ALD, for example PEALD (plasma-enhanced atomic layer deposition), or for photon-assisted ALD, one or more of the deposition steps can be assisted by providing required additional energy for surface reactions through plasma or photon in-feed, respectively. Or one of the reactive precursors can be substituted by energy, leading to single precursor ALD processes. Accordingly, the pulse and purge sequence may be different depending on each particular case. The deposition cycles form a timed deposition sequence that is controlled by a logic unit or a microprocessor. Thin films grown by ALD are dense, pinhole free and have uniform thickness.

As for substrate processing steps, the at least one substrate is typically exposed to temporally separated precursor pulses in a reaction vessel (or chamber) to deposit material on the substrate surfaces by sequential self-saturating (or self-limiting) surface reactions. In the context of this application, the term ALD comprises all applicable ALD based techniques and any equivalent or closely related technologies, such as, for example the following ALD sub-types: MLD (Molecular Layer Deposition), plasma-assisted ALD, for example PEALD (Plasma Enhanced Atomic Layer Deposition) and photon-assisted or photon-enhanced Atomic Layer Deposition (known also as flash enhanced ALD or photo-ALD).

However, the invention is not limited to ALD technology, but it can be exploited in a wide variety of substrate processing methods, for example, in Chemical Vapor Deposition (CVD) and other thin film depositions.

In context of ALD techniques, the self-limiting surface reaction means that the surface reactions on the reactive layer of the surface will stop and self-saturate when the surface reactive sites are entirely depleted.

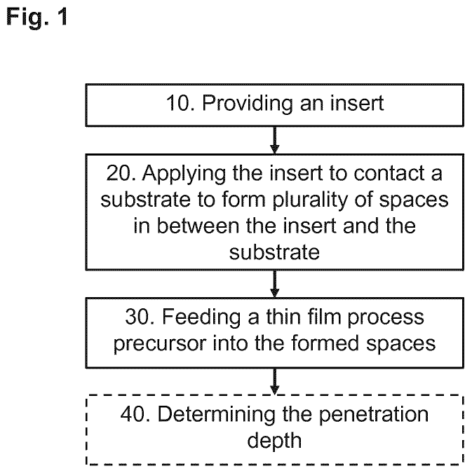

FIG. 1. presents a flow chart of a method for determining penetration depth of a thin film process precursor, comprising providing an insert (10), arranging the insert to contact a substrate to form a plurality of spaces in between the insert and the substrate (20), and feeding the precursor into the formed spaces (30) to determine the penetration depth of the precursor. According to an additional embodiment, the method comprises determining the penetration depth (40) by measuring the thin film coating formed on the substrate. In certain embodiments, the insert and the substrate are housed by a reaction chamber of a deposition reactor, such as an ALD apparatus (or an ALD reactor).

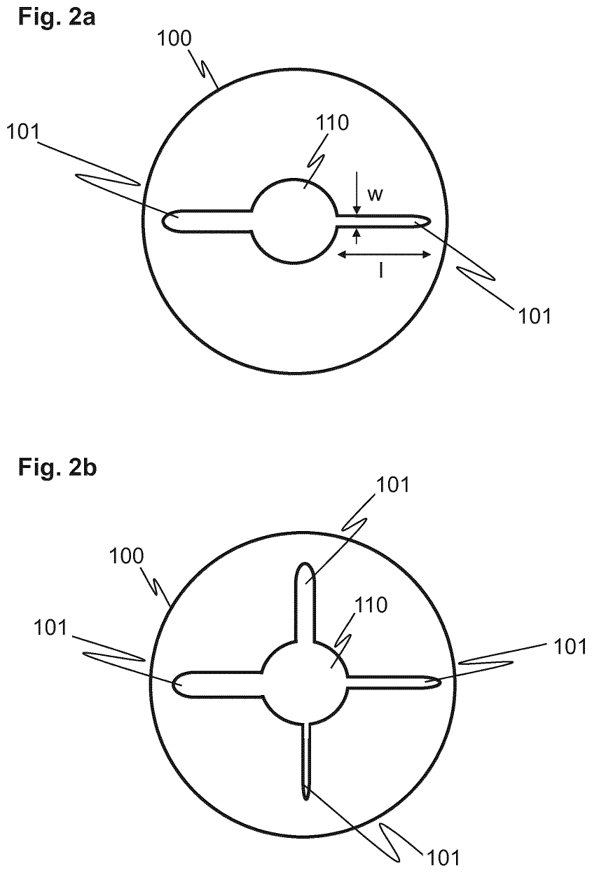

FIG. 2a presents an example of an insert 100. In particular, FIG. 2a shows a bottom view of the insert 100, wherein the insert 100 in this example is in the general shape of a disk. The insert 100 comprises two grooves in its bottom surface. The insert 100 further comprises an aperture (through hole) 110 in the centre of the insert 100. The grooves have entry openings in a wall surrounding the aperture 110. The grooves are configured to form spaces 101 in between the insert 100 and a substrate, such as a wafer, when the insert 100 is applied to contact the substrate. In the context of the present description, each space 101 has a width, a height, and a depth (length). The width w of the space 101 is the dimension of the space 101 visible from the bottom, which is perpendicular to the direction of the radius of the insert 100. The length l of the space 101 is the dimension of the space 101 that is parallel to the direction of the radius of the insert 100, when observing the insert from the bottom. The height h of the space 101 is the remaining dimension of the insert 100 perpendicular to both w and l.

According to an embodiment, as shown in FIG. 2a, the spaces 101 have varying widths w. According to this embodiment, the other dimensions (respective heights and respective lengths) of each space 101 are equal.

FIG. 2b presents an example of an insert 100 comprising four grooves, which grooves are configured to form spaces 101 in between the insert 100 and a substrate when the insert 100 is applied to contact the substrate. According to an embodiment, the spaces 101 have varying widths. The other dimensions (respective heights and respective lengths) of each space 101 are equal.

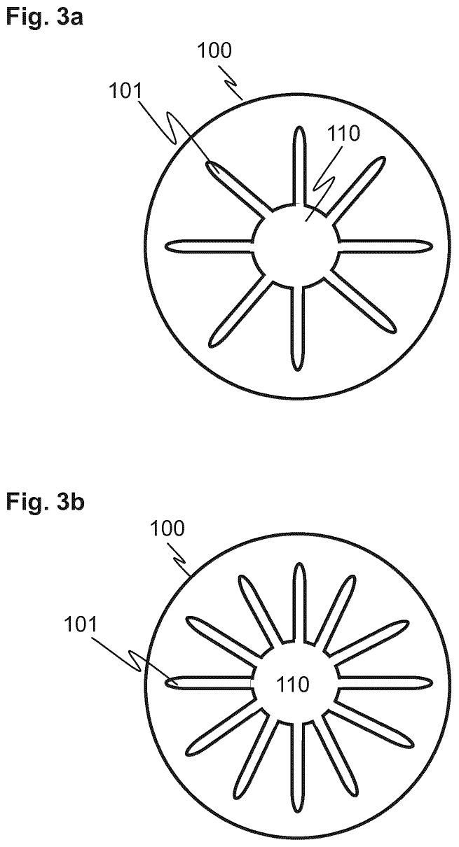

FIG. 3a presents an example of an insert 100 comprising eight grooves, which grooves are configured to form spaces 101 in between the insert 100 and a substrate when the insert 100 is applied to contact the substrate. According to this particular embodiment, the spaces 101 have varying heights. The other dimensions (respective widths and respective lengths) of each space 101 are equal.

FIG. 3b presents an example of an insert 100 comprising twelve grooves, which grooves are configured to form spaces 101 in between the insert 100 and a substrate when the insert 100 is applied to contact the substrate. According to this particular embodiment, the spaces 101 have varying heights. The other dimensions (respective widths and respective lengths) of each space 101 are equal.

FIG. 3c presents an example of an insert 100 comprising bendy grooves, which grooves are configured to form spaces 101 in between the insert 100 and a substrate when the insert 100 is applied to contact with the substrate. The bendy shape of the grooves allows the spaces 101 to be longer than straight spaces 101. According to this particular embodiment, the spaces 101 have varying heights. The other dimensions (respective widths and respective lengths) of each space 101 are equal.

According to certain embodiments, a plurality of spaces 101 form in between the insert 100 and the substrate 200 when applying the insert 100 to contact a substrate (or substrate surface). In certain embodiments, the number of the spaces 101 is at least two.

As presented in the foregoing with reference to FIGS. 2a, 2b, 3a and 3b, the insert 100 comprises the aperture 110 in the centre of the insert 100. The aperture 110 is in flow-communication with the spaces 101 to allow the precursor to be fed to the spaces 101 through the aperture 110 of the insert 100. According to an embodiment, the precursor enters the spaces 101 and flows within the spaces 101 via diffusion. As presented in FIGS. 2a, 2b, 3a and 3b, the insert 100 is disk shaped and/or the shape of the insert 100 is symmetrical around its centre.

In certain embodiments, the spaces 101 are elongated, confined, and/or closed at their one end. In certain embodiments, the spaces 101 are closed at their one end located opposite to the mouth of the space 101 (the mouth of the space 101 being in the wall of the aperture 110). The spaces 101 have varying widths or varying heights depending on the embodiment. In certain embodiments, the spaces 101 have same lengths.

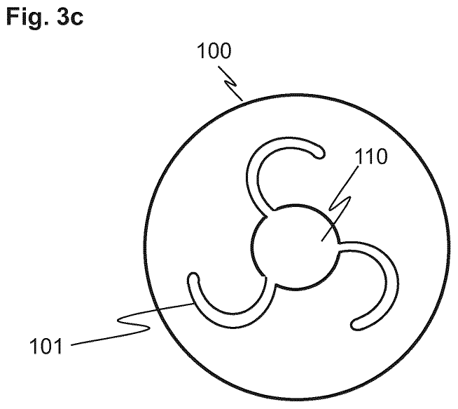

FIG. 4a presents a location of a cross-section of the insert 100 of FIG. 3a. The cross-section is marked with a dashed line. The cross-section cuts the grooves that form the spaces 101 together with the substrate.

FIG. 4b presents the cross-section of the insert 100 according to the cross-section line marked in FIG. 4a. In this embodiment, the spaces 101 have varying heights h1 and h2. In certain embodiments, as shown in FIG. 4b, the heights h1 and h2 are constant. According to other embodiment, the spaces 101 have radially decreasing heights.

Different dimensions of the spaces 101 allow the precursor to travel varying distances in the individual spaces 101. In wider or higher spaces 101, the precursor penetrates deeper than in narrow or shallow spaces 101. The thin film process variables such as processing pressure, precursor pulse duration and duration between the precursor pulses have an effect on the precursor penetration depth. Thus, by varying the thin film process variables, the precursor penetrates different depths in the spaces 101. The height dimension is exaggerated in FIG. 4b for an illustrative purpose.

In certain embodiments, the insert 100 is composed of a composite material of a polymer and a rigid material. The polymer material is preferably relatively soft and heat resistant, such as polymethyl methacrylate (PMMA), polydimethylsiloxane (PDMS), polytetrafluoroethylene (PTFE) or alike. The rigid material is preferably a metal or ceramic plate. In this example embodiment, the grooves of the insert 100 that form spaces 101, when the insert is applied to contact a substrate, are imprinted on the polymer material and the rigid material is included to the insert 100 to maintain the form of the polymer and to ease handling. An achieved additional technical effect is improved compensation of the change of shape due to thermal expansion via the polymer material.

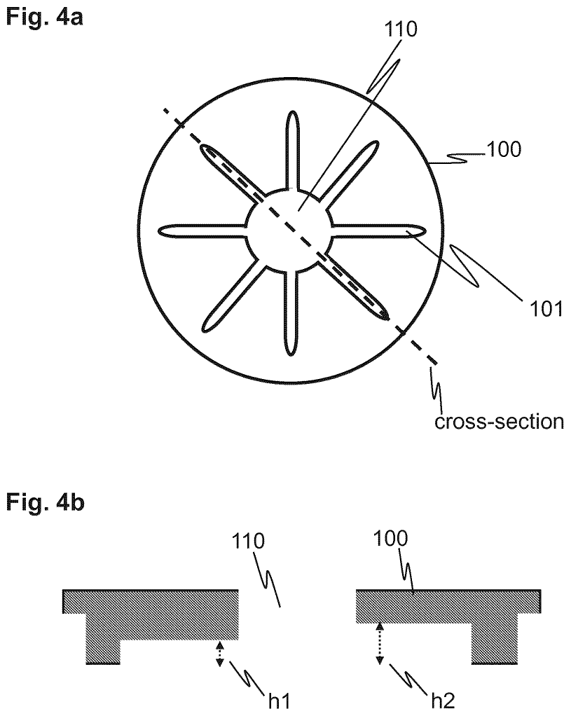

FIG. 5a presents a location of a further cross-section of the insert 100 of FIG. 3a. The cross-section is marked with a dashed line. The cross-section cuts the insert 100 at an area in between the grooves that form the spaces 101.

FIG. 5b presents the cross-section of the insert 100 according to the cross-section line marked in FIG. 5a. The insert 100 has a diameter d1. The insert 100 has a body that has even thickness in the areas that do not form the spaces 101. Thus, the spaces 101 are separate from each other, preventing the precursor flow from one space 101 to adjacent spaces 101.

FIG. 5c presents schematically a magnified view of an edge of the insert 100. In certain embodiments, the edge of the insert 100 has a horizontally extending protrusion 120. The protrusion 120 allows the insert to be moved, lifted and lowered. In certain embodiments, the protrusion 120 is positioned at an upper corner of the edge of the insert 100. The diameter d1 represents an outer diameter of the insert 100 from edge to edge at an area of the edge lacking the protrusions 120.

According to an optional embodiment, the insert 100 has a vertical protrusion (a notch) 130 protruding from the outer edge of the bottom of the insert 100. The protrusion 130 allows the insert 100 and the substrate 200 to be centered. The protrusion 130 is a guide in alignment of the insert 100 and the substrate 200.

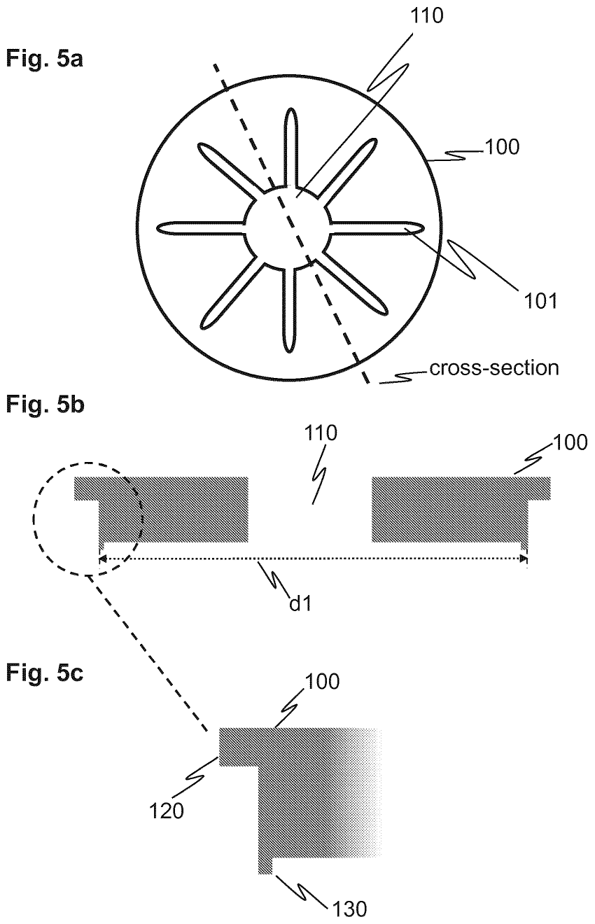

FIG. 6a presents a cross-section of a substrate holder 300 according to certain embodiments. In certain embodiments, a top surface of the substrate holder 300 has the shape of a round plate. In certain embodiments, the round plate receives a substrate, and the insert is positioned onto the substrate prior the in-feed of the precursor(s). The substrate holder 300 has an inner diameter d2 and an outer diameter d3.

FIG. 6b presents schematically a magnified view of an edge of the substrate holder 300. The edge of the substate holder 300 has a protrusion 310. The protrusion 310 allows the insert to be moved, lifted and lowered. The protrusion 310 allows the substrate to be placed on top of the substrate holder 300. The protrusion 310 prevents the substrate from sliding or moving on top of the substrate holder 300.

FIG. 6c shows the substrate holder 300 from above. The protrusion 310 is visible from above and the protrusion 310 goes around a circular edge of the substrate holder 300. The inner diameter d2 of the substrate holder 300 is smaller than the outer diameter d3 of the substrate holder 300. In certain embodiments, the substrate holder 300 has an indent 320, or at least two indents 320 as shown in FIG. 6c. The said indents 320 allow a loading tool or a tool operator to grip the substrate.

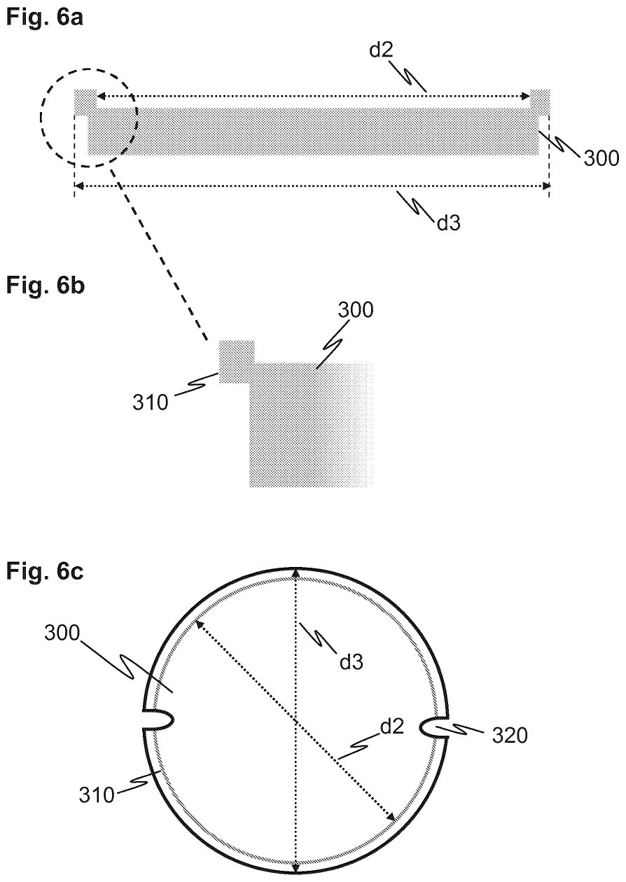

FIG. 7a presents the insert 100, the substrate 200 and the substrate holder 300 as a side view. The substrate 200 is placed on top of the substrate holder 300. The diameter d1 of the insert 100 is smaller than the inner diameter d2 of the substrate holder 300 but just larger than the diameter of the substrate 200. The insert 100 is placed on top of the substrate 200. The substrate 200 and the insert 100 are in contact to form the plurality of spaces 101 in between the insert 100 and the substrate 200. According to an embodiment, when the insert 100 and the substrate 200 are horizontally oriented, the insert 100 is (or rests) on top of the substrate 200. In certain embodiments, a bottom side of the insert 100 is in contact with a top side of the substrate 200 except in positions in which the aperture 110 and the spaces 101 are located (and at the location of the optional protrusion (notch) 130 that merely surrounds the substrate 200).

FIG. 7b presents the insert 100, the substrate 200 and the substrate holder 300 including the feed of the precursor(s). The feeding of the precursor(s) occurs through the aperture 110 in the centre of the insert 100.

FIG. 7c presents a flow path of the precursor. As mentioned, the feeding of the precursor(s) occurs through an aperture 110 in the centre of the insert 100. The aperture 110 is in flow-communication with the formed spaces (or high aspect ratio structures) 101 to allow the precursor(s) to enter the spaces 101 through the aperture 110 of the insert 100. The precursor(s) flows first downwards through the aperture 110, and when it approaches the substrate 200 surface, the precursor flow turns and flows horizontally along the substrate 200 surface into the spaces 101. According to an embodiment, the precursor(s) enters the spaces 101 via diffusion. The spaces 101 have varying widths or varying heights. In certain embodiments, the spaces 101 have same lengths. Therefore, the precursor flow penetrates the spaces 101 varying depths. Whilst penetrating the spaces 101, the precursor(s) forms a thin film on the substrate 200 surface. After the precursor flow has reached its maximum penetration depth, the remaining precursor(s) and reaction by-products (if any) flow back through the aperture 110. Then, they flow along the surface of the insert 100 and over the edge of the insert 100, after which they exit the reaction space and are removed via an exhaust line (not shown).

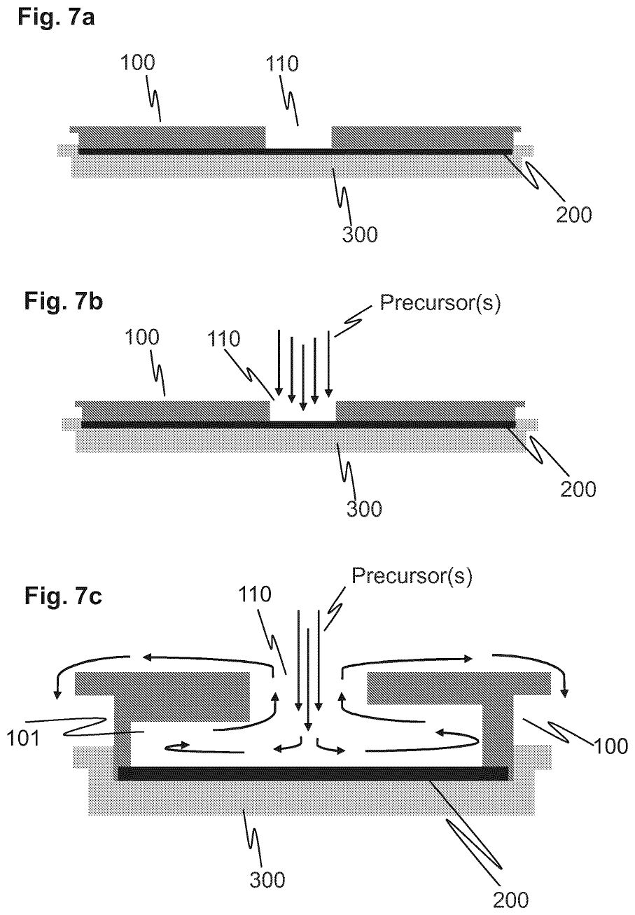

FIG. 8 presents a magnified view of the insert 100, the substrate 200 and the substrate holder 300 edges as a side view. The protrusion 130 allows the insert 100 and the substrate 200 to be centered with respect to each other. The protrusion 130 is a guide in alignment of the insert 100 and the substrate 200. According to an embodiment, the method comprises obtaining results from the measurement of the thin film formed on the substrate and adjusting the thin film process according to the obtained results. According to an embodiment, the measuring comprises analysis of precursor penetration depth via quantitative visual inspection, or ellipsometry characterization, or other suitable characterization technique. The ellipsometry characterization or other suitable characterization technique is performed via a suitable measurement apparatus (or device). In certain embodiments, the measuring of the precursor penetration depth is performed from the aperture 110 towards the ends of the spaces 110.

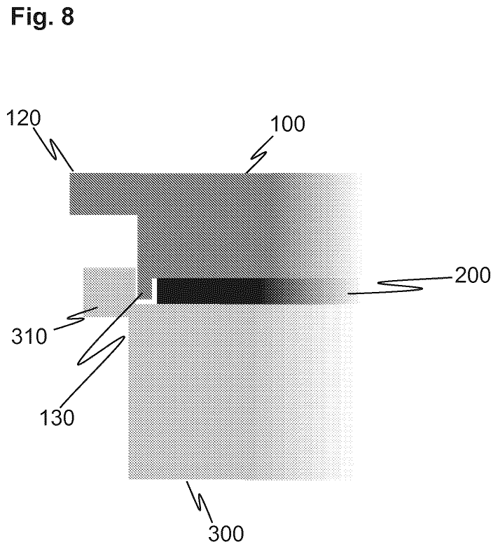

Monitoring and process control of the thin film deposition occurs by quantifying the penetration depth of the thin film deposition. FIG. 9a shows the substrate 200 after the precursor deposition. According to an embodiment, it can be determined with a naked eye, through quantitative visual inspection, how the thin film deposition has formed thin film into the spaces 101 (and onto the underlying substrate 200). The thin film deposition forms an image 210 on the substrate 200, in which it can be observed visually how the penetration depths vary between the spaces 101 with varying widths or heights.

The quantitative visual inspection may comprise comparing the formed thin film image 210 to a glass disk, which has a scale written. In this case, the visual inspection comprises comparing the formed image 210 to the scales on the glass disk. The operator is able to take a note of the readings that the scales on the glass disk present and compare those readings to the known values of the optimal operating conditions. By comparing the scale readings, the operator is able note if the process conditions at the time of the monitoring are not optimal.

In a processing facility, there may be provided a model substrate with an ideal image representing ideal process conditions for process monitoring purposes. The model substrate can be obtained by coating a substrate according to the disclosed method in found optimal operating conditions to produce the ideal image. For the purpose of process control and/or monitoring, an operator may perform the disclosed method later with the existing process conditions to form a “monitor substrate” (or a substrate with an image during monitoring). After that, the operator can compare visually the monitor substrate with the model substrate. The operator is able to note if the process conditions at the time of the monitoring are not optimal. The operator then can adjust the process variables accordingly to improve the process quality.

The ellipsometry characterization comprises characterization of the penetration depth of the precursor(s). In an embodiment, the ellipsometry characterization may comprise further characterization of the thickness profile of the thin film. A computer program may be used to aid the operator in data analysis and visualization of the ellipsometry characterization for higher efficiency and repeatability. FIG. 9b shows a visualization of penetration depth analysis results in certain embodiments. The visualization labels a number of tunnels with different tunnel heights and shows penetration depths in the tunnels as well as the thickness of thin film coating formed on the substrate.

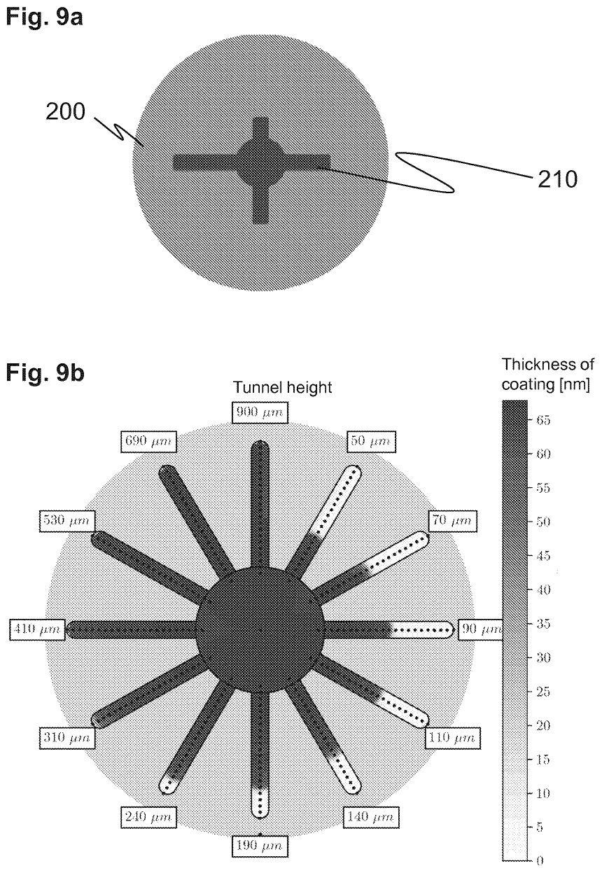

FIG. 10 shows a block diagram of a computerized process control system of a deposition apparatus or reactor in accordance with certain example embodiments. The control system 750 comprises at least one processor 751 to control the operation of the apparatus and at least one memory 752 comprising a computer program or software 753. The software 753 includes instructions or a program code to be executed by the at least one processor 751 to control the apparatus. The software 753 may typically comprise an operating system and different applications. The control system 750 may be configured as a computerized system, which uses one or more computers.

The at least one memory 751 may form part of the apparatus or it may comprise an attachable module. The control system 750 further comprises at least one communication unit 754. The communication unit 754 provides for an interface for internal communication of the measurement apparatus. In certain embodiments, the control unit 750 uses the communication unit 754 to send instructions or commands to and to receive data from different parts of the apparatus, for example, measuring and control devices, valves, and other adjustment devices (not shown).

The control system 750 may further comprise a user interface 756 to co-operate with an operator, for example, to receive input such as process parameters from the operator. In certain embodiments, the user interface 756 is connected to the at least one processor 751.

As to the operation of the apparatus, the control system 750 controls e.g. the in-feed of precursor vapor into the plurality of spaces formed in between the insert 100 and the substrate 200 for determining the penetration depth.

In certain embodiments, the control system 750 comprises a measurement device 757 that provides measurement(s), such as ellipsometry characterization measurement for further analysis. In accordance with certain embodiments, the measurement device 757 is configured, by means of being programmed, for example, to perform a measurement sequence to the substrate 200. In accordance with certain embodiments, the measurement device 757 is programmed to collect the results of the measurement(s) (measurement data) performed during the measurement sequence.

As a part of the control system 750, or separate from the control system 750, a program module can be implemented, which analyses obtained measurement data. In certain embodiments, the program module (or program code) is implemented in said software 753. In accordance with certain embodiments, the at least one processor 751 performs data analysis to the obtained measurement data. In accordance with certain embodiments, measurement data received or obtained from the measurement device 757 are analyzed by the at least one processor 751 to determine the penetration depth, and an operator is provided with measurement results and/or visualization based on the analysis. The measurement results/visualization may be presented at the user interface 156 or at a separate display device.

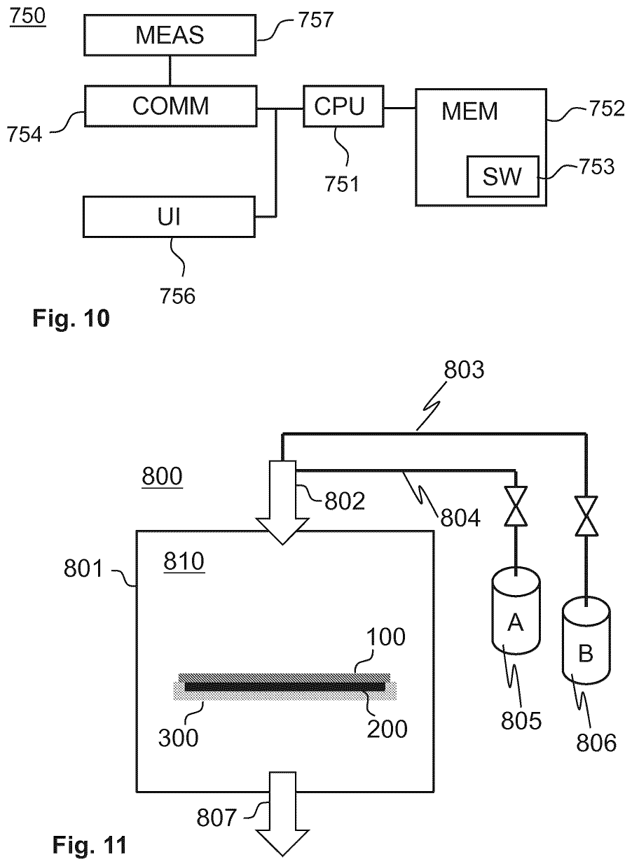

FIG. 11 schematically shows an apparatus 800, such as an ALD reactor or another deposition apparatus, configured to perform the disclosed method in accordance with certain embodiments. The apparatus 800 comprises a reaction chamber 801 that encloses a reaction space 810. The reaction space 810 may be heated. The reaction chamber 801 houses the substrate 200 and the insert 100 in contact with the substrate 200. In certain embodiments, the substrate 200 and the insert 100 are supported by the substrate holder 300. Precursors (A, B) (or precursor vapor) are fed into the reaction chamber 801 through an inlet 802. The precursors (A, B) are fed into the inlet 802 via individual pipelines 803, 804 from individual precursor containers 805, 806. In the event of ALD processing, the precursors (A, B) are fed alternately. After the apparatus 800 has performed the thin film deposition process, the remaining precursors (A, B) exit the reaction chamber 801 via an exhaust line 807. In an embodiment, the in-feed of the two precursors (A, B) is from a top portion of the reaction chamber 801 and the exhaust from the bottom.

Without limiting the scope and the interpretation of the patent claims, certain technical effects of one or more of the example embodiments disclosed herein are listed in the following. A technical effect of the invention is making a thin film deposition process control and monitoring faster and cheaper. A further technical effect is reducing the downtime in a production due to faster process control and monitoring. A further technical effect is adjusting the thin film deposition process more agile. A further technical effect is allowing a quantitative visual inspection in the process control and monitoring. A further technical effect is that the same insert can be used multiple times, i.e. the insert is re-usable. This minimizes the amount of waste, which would result from using single-use process control and/or monitoring means.

Various embodiments have been presented. It should be appreciated that in this document, words comprise, include, and contain are each used as open-ended expressions with no intended exclusivity.

The foregoing description has provided by way of non-limiting examples of particular implementations and embodiments a full and informative description of the best mode presently contemplated by the inventors for carrying out the invention. It is however clear to a person skilled in the art that the invention is not restricted to details of the embodiments presented in the foregoing, but that it can be implemented in other embodiments using equivalent means or in different combinations of embodiments without deviating from the characteristics of the invention.

Furthermore, some of the features of the afore-disclosed example embodiments may be used to advantage without the corresponding use of other features. As such, the foregoing description shall be considered as merely illustrative of the principles of the present invention, and not in limitation thereof. Hence, the scope of the invention is only restricted by the appended patent claims.

1. A method for determining penetration depth of thin film process precursor(s), comprising:
providing an insert;
arranging the insert to contact a substrate to form a plurality of spaces in between the insert and the substrate; and
feeding the precursor(s) into the formed spaces to determine the penetration depth of the precursor(s).

2. The method of claim 1, comprising:
feeding the precursor(s) into the formed spaces in a reaction chamber housing the insert and the substrate.

3. The method of claim 1, comprising:
feeding the precursor(s) into the formed spaces by using an atomic layer deposition (ALD) sequence.

4. The method of claim 1, wherein the formed spaces are elongated spaces open at their one end, closed at their other end, and confined by the substrate and/or the insert along their width, the spaces preferably forming high aspect ratio structures.

5. The method of claim 1, wherein the insert comprises grooves, which grooves are configured to form said spaces in between the insert and the substrate when the insert and the substrate are in contact with each other.

6. The method of claim 1, wherein the spaces have varying widths or varying heights.

7. The method of claim 1, wherein the spaces are separate from each other, preventing the precursor(s) from flowing from one space directly into an adjacent space.

8. The method of claim 1, wherein the insert is disk shaped and/or the shape of the insert is symmetrical around its centre.

9. The method of claim 1, wherein the insert comprises an aperture in the centre of the insert, and the aperture is connected to the spaces to allow precursor feed into the spaces through the aperture of the insert.

10. The method of claim 1, wherein the precursor(s) flow within the spaces via diffusion.

11. The method of claim 1, wherein the insert and the substrate are horizontally oriented, the insert resting on top of the substrate.

12. The method of claim 1, comprising:
determining the penetration depth by measuring a thin film coating formed on the substrate.

13. The method of claim 12, comprising:
obtaining results from the measurement of the thin film formed on the substrate and adjusting the thin film process according to the obtained results.

14. The method of claim 12, wherein said determining comprises:
analyzing obtained measurement data by at least one processor; and
providing an operator with measurement results based on the analysis.

15. An insert configured to contact a substrate to form a plurality of spaces in between the insert and the substrate for determining penetration depths of thin film process precursor(s) with the method of claim 1.

16. The insert of claim 15, comprising grooves configured to form said spaces when the insert and the substrate contact each other.

17. The insert of claim 15, wherein the insert is removable.

18. The insert of claim 15, wherein the insert is re-usable.

19. An apparatus comprising at least one processor, and at least one memory including computer program code, wherein the at least one memory and the computer program code are configured, with the at least one processor, to cause the apparatus to perform:
feeding of precursor(s) into a plurality of spaces formed in between an insert and a substrate by arranging the insert to contact the substrate; and
determining the penetration depth of the precursor(s) in the formed spaces.

20. A computer program comprising computer executable program code which when executed by a processor causes an apparatus to perform:
feeding of precursor(s) into a plurality of spaces formed in between an insert and a substrate by arranging the insert to contact the substrate; and
determining the penetration depth of the precursor(s) in the formed spaces.
